(19) United States
(12) Patent Application Publication
(10) Pub. No.: US 2015/0262679 A1
(43) Pub. Date: Sep. 17, 2015

(54) SEMICONDUCTOR MEMORY DEVICE AND METHOD OF CONTROLLING THE SAME

(71) Applicant: KABUSHIKI KAISHA TOSHIBA, Minato-ku (JP)

(72) Inventor: Yasuhiro SHIMURA, Yokkaichi-shi (JP)

(73) Assignee: KABUSHIKI KAISHA TOSHIBA, Minato-ku (JP)

(21) Appl. No.: 14/457,414

(22) Filed: Aug. 12, 2014

Related U.S. Application Data
(60) Provisional application No. 61/952,333, filed on Mar. 13, 2014.

(51) Int. Cl. G11C 16/10; G11C 16/34; G11C 16/04

(52) U.S. Cl. CPC G11C 16/10; G11C 16/0408; G11C 16/0483; G11C 16/3459

(57) ABSTRACT

A semiconductor memory device according to an embodiment comprises: a nonvolatile memory cell and a control circuit. The control circuit executes: a first write operation that performs a write on the memory cell using a first write voltage; a first verify operation that determines whether a threshold voltage of the memory cell exceeds a first threshold value due to the first write operation, or not; a second verify operation that re-determines on the memory cell that has passed the first verify operation whether the threshold voltage exceeds the first threshold value, or not; and a second write operation that performs a write on the memory cell that has not passed the second verify operation, using a second write voltage.

### CROSS REFERENCE TO RELATED APPLICATION

This application is based on and claims the benefit of priority from prior U.S. Provisional Patent Application No. 61/952,333, filed on Mar. 13, 2014, the entire contents of which are incorporated herein by reference.

### FIELD

Embodiments described in the present specification relate to a semiconductor memory device and a method of controlling the same.

### BACKGROUND

In a nonvolatile semiconductor memory device such as a NAND type flash memory, a memory cell includes a control gate and a charge accumulation layer, and stores as data a magnitude of a threshold voltage of the memory cell that changes according to a charge accumulated in the charge accumulation layer. In such a semiconductor memory device, the threshold voltage sometimes lowers with passing time.

### BRIEF DESCRIPTION OF THE DRAWINGS

FIG. 1 is an overall block diagram of a semiconductor memory device according to a first embodiment.

FIG. 2 is a circuit diagram showing a detailed configuration of a memory cell array.

FIG. 3 includes schematic views showing threshold voltages of a memory cell during data write.

FIG. 4 is a (first) flowchart showing data write control of the semiconductor memory device according to the first embodiment.

FIG. 5 is a (second) flowchart showing data write control of the semiconductor memory device according to the first embodiment.

FIG. 6 is a signal diagram of during data write of the semiconductor memory device according to the first embodiment.

FIG. 7 is a flowchart showing data write of a semiconductor memory device according to a modified example of the first embodiment.

FIG. 8 is a (first) flowchart showing data write control of a semiconductor memory device according to a second embodiment.

FIG. 9 is a (second) flowchart showing data write control of the semiconductor memory device according to the second embodiment.

FIG. 10 is a signal diagram of during data write of the semiconductor memory device according to the second embodiment.

FIG. 11 is a flowchart showing data write of a semiconductor memory device according to a modified example of the second embodiment.

FIG. 12 is a schematic perspective view of a part of the memory transistor region of the semiconductor memory device.

FIG. 13 is a partly enlarged sectional view of FIG. 12.

### DETAILED DESCRIPTION

A semiconductor memory device according to an embodiment comprises: a nonvolatile memory cell; and a control circuit that performs write control on the memory cell. The control circuit executes: a first write operation that performs a write on the memory cell using a first write voltage; a first verify operation that determines whether a threshold voltage of the memory cell exceeds a first threshold value due to the first write operation, or not; a second verify operation that re-determines on the memory cell that has passed the first verify operation whether the threshold voltage exceeds the first threshold value, or not; and a second write operation that performs a write on the memory cell that has not passed the second verify operation, using a second write voltage.

### First Embodiment

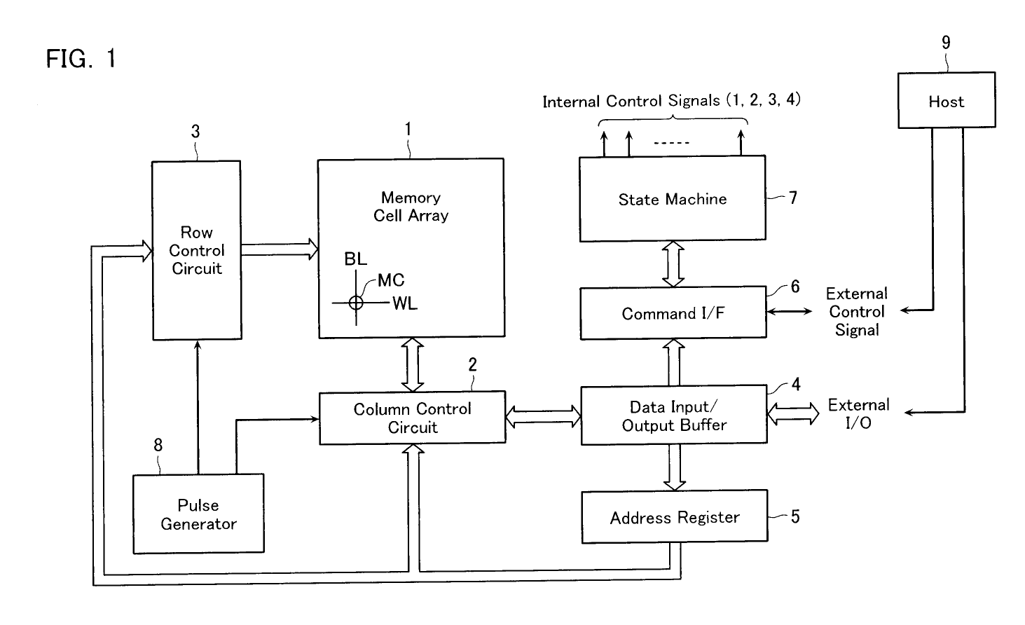

FIG. 1 is a block diagram showing a configuration of a nonvolatile semiconductor memory device according to a first embodiment. The present semiconductor memory device is a NAND type flash memory adopting a four-level storage system. The present semiconductor memory device comprises a memory cell array 1 having a plurality of data-storing memory cells MC disposed in a matrix therein. The memory cell array 1 includes a plurality of bit lines BL and a plurality of word lines WL that intersect each other, and has the memory cell MC disposed at each of intersections of said bit lines BL and word lines WL. The memory cell MC has a stacked structure of a floating gate electrode which functions as a charge accumulation layer that accumulates a charge, and a control gate electrode which is connected to the word line WL. The memory cell MC is configured capable of electrically rewriting data by injection or release of charge into/from the floating gate electrode.

Connected to the memory cell array 1 are a column control circuit 2 for controlling a voltage of the bit line BL, and a row control circuit 3 for controlling a voltage of the word line WL. The column control circuit 2 reads data from the memory cell MC via the bit line BL and performs write of data to the memory cell MC via the bit line BL. The row control circuit 3 applies a voltage for write, read, and erase of data, to a gate electrode of the memory cell MC, via the word line WL.

Connected to the column control circuit 2 is a data input/output buffer 4. Data of the memory cell MC read by the column control circuit 2 is outputted to an external host 9 from a data input/output terminal (external I/O) via the data input/output buffer 4. Moreover, write data inputted to the data input/output terminal (external I/O) from the external host 9 is inputted to the column control circuit 2 via the data input/output buffer 4, and is written to a designated memory cell MC.

Connected to the data input/output buffer 4 are an address register 5 and a command I/F 6. The address register 5 outputs address information inputted from the data input/output buffer 4, to the column control circuit 2 and the row control circuit 3. The command I/F 6 is connected to a state machine 7 and the external host 9, and sends/receives a control signal between these blocks. Connected to the state machine 7 are the memory cell array 1, the column control circuit 2, the row control circuit 3, and the data input/output buffer 4. The state machine 7 generates an internal control signal for controlling the memory cell array 1, the column control circuit 2, the row control circuit 3, and the data input/output buffer 4, based on an external control signal inputted from the host 9 via the command I/F 6.

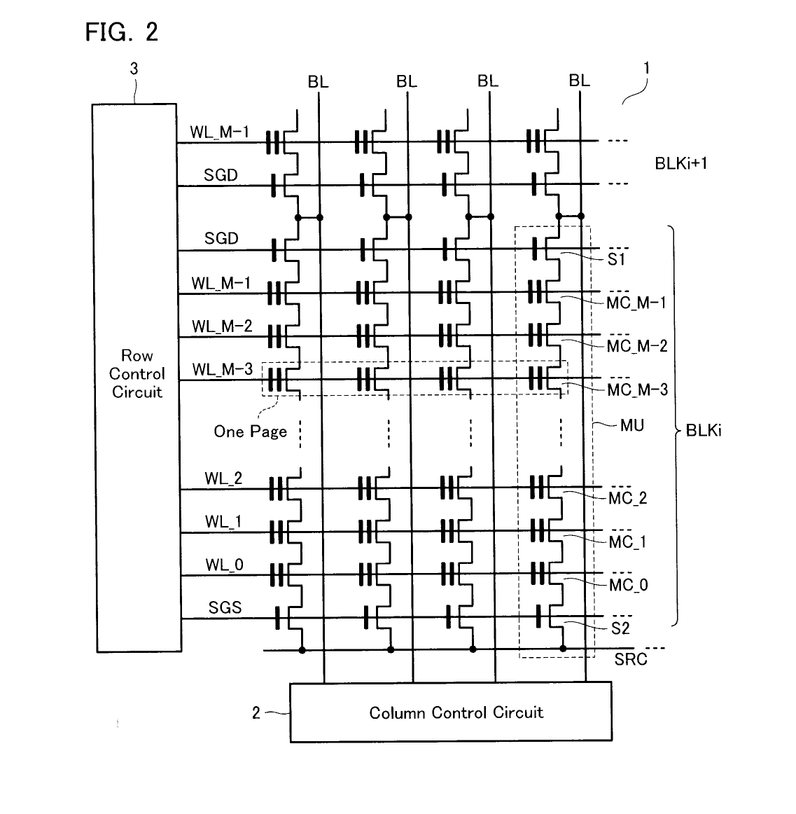

FIG. 2 is a circuit diagram showing a configuration of a part of the memory cell array 1 shown in FIG. 1.

The memory cell array 1 includes a plurality of memory units MU. The memory unit MU is configured from M (for example, M=16) memory cells MC_0 to MC_M−1 connected in series, and a first select gate transistor S1 and a second select gate transistor S2 connected to the two ends of these series-connected memory cells MC_0 to MC_M−1. One end of the first select gate transistor S1 is connected to the bit line BL, and one end of the second select gate transistor S2 is connected to a source line SRC. That is, the memory cells MC are arranged in series, sandwiched by a plurality of select transistors (S1 and S2), in a region of intersection of the word line WL and the bit line BL.

Word lines WL_0 to WL_M−1 are connected to the control gate electrodes of the memory cells MC_0 to MC_M−1. The plurality of memory units MU are disposed in a direction of formation of the word line WL, and form one block BLKi. In the memory cell array 1, erase of data is performed in a block BLK unit. Moreover, the plurality of memory cells MC commonly connected to one word line WL form one page. In the memory cell array 1, write and read of data are performed in a one page unit.

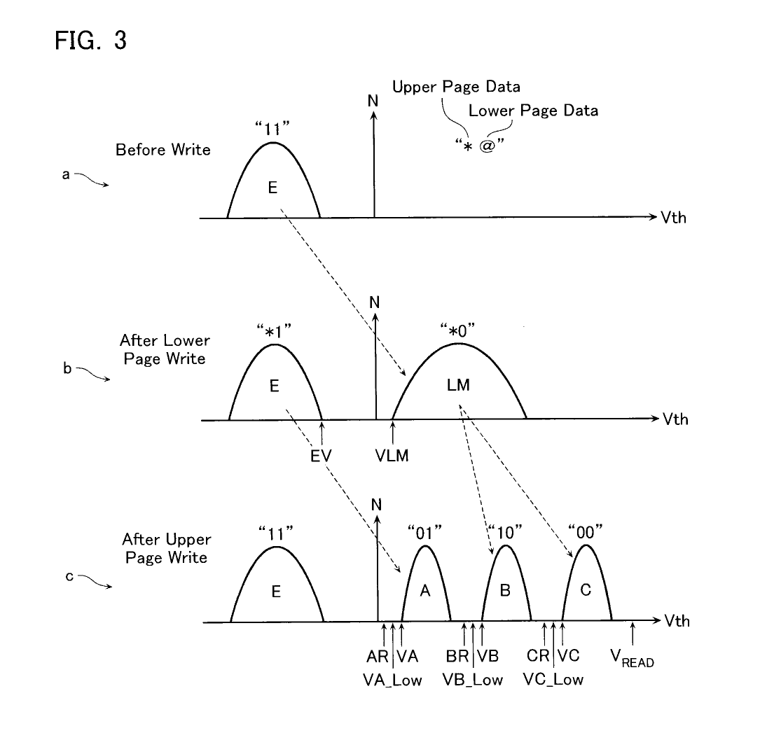

Next, an outline of a data storage system of the nonvolatile semiconductor memory device will be described. The nonvolatile semiconductor memory device is configured such that a threshold voltage of the memory cell MC can have four kinds of distributions. FIG. 3, in a to c thereof, includes views showing a relationship between change in a threshold voltage distribution of the memory cell MC and two-bit four-level data stored in the memory cell MC during data write of the nonvolatile semiconductor memory device. The four-level data are specified by, for example, a negative threshold voltage distribution (erase distribution) E having a lowest level of voltage level, and threshold voltage distributions A, B, and C having higher voltage levels than that of the threshold voltage distribution E. In the present embodiment, the threshold voltage distributions E, A, B, and C are assumed to correspond to data “11”, “01”, “10”, and “00”, respectively.

First, as shown in a of FIG. 3, before write, the memory cells included in the write-target block (refer to BLKi of FIG. 2) are all set to the erase state threshold voltage distribution (E) by data erase. This data erase is performed by, for example, applying a positive erase voltage (Vera, not illustrated in FIG. 3) to a well where the memory cell array 1 is formed, and setting a potential of all word lines WL of the selected block to 0 V, thereby releasing electrons from the floating gates of all memory cells MC.

Next, as shown in b of FIG. 3, some of the memory cells MC in the erase state (E) undergo a lower page write (Lower Page Program) that raises their threshold voltage to an intermediate voltage distribution (LM). Then, a verify operation for verifying completion of the lower page write is performed by setting a verify voltage to a voltage VLM and applying said voltage between the gate and the source of the memory cell MC. If the memory cell MC conducts due to the verify voltage VLM, then write fail (FAIL) is determined, and if the memory cell MC does not conduct due to the verify voltage VLM, then write pass (PASS) is determined. As a result, the threshold voltage of the memory cell MC that has undergone the lower page write rises and undergoes transition to the intermediate threshold voltage distribution (LM).

Next, as shown in c of FIG. 3, an upper page write (Upper Page Program) is performed that raises some of the memory cells MC in the erase state (E) to the threshold voltage distribution A and raises the memory cell MC in the intermediate voltage distribution (LM) to the threshold voltage distribution B or C. Then, similarly to in the case of the lower page write, a verify operation for verifying completion of the upper page write is performed by setting a verify voltage to, respectively, VA, VB, and VC and applying said voltage between the gate and the source of the memory cell MC. As a result, the threshold voltage of the memory cell MC that has undergone the upper page write rises and undergoes transition to any one of the threshold voltage distributions A, B, and C.

In the above data write operation, the selected word line to which one page of write-target memory cells MC are connected is provided with a write voltage VPGM (about 20 to 28 V), and another non-selected word line is provided with a write pass voltage Vpass (about 8 to 10 V). On that basis, the bit line electrically connected to the write-target memory cell MC is selectively provided with a ground voltage Vss (in the case of “0” write) or a power supply voltage VDD (in the case of “1” write). As a result, electrons are selectively injected into the floating gate of the memory cell MC.

In the case of “0” write that raises the threshold voltage, the ground voltage Vss provided to the bit line is transmitted to a channel of the NAND cell unit via the first select gate transistor S1 set to a conductive state. As a result, when the write voltage VPGM is provided, a tunnel current flows between the channel and the floating gate, and electrons are injected into the floating gate. On the other hand, in the case of “1” write that does not raise the threshold voltage (write inhibit), the bit line is provided with the power supply voltage VDD. In this state, even if the power supply voltage VDD is provided to the first select gate transistor S1, the channel of the NAND cell unit is charged to VDD−Vt (Vt is the threshold voltage of the first select gate transistor S1) to be in a floating state. As a result, when the write voltage VPGM is provided, the cell channel is boosted by capacitive coupling, and electron injection into the floating gate does not occur. Note that the present embodiment adopts a step-up system that, during data write, raises the write voltage little by little each write cycle (a combination of one time of a write operation and one time of a verify operation being assumed to be one cycle).

During read of data, read voltages RA, RB, and RC which are voltages between upper limits and lower limits of each of the threshold voltage distributions E to C are applied between the gate and the source of the read-target selected memory cell MC. Moreover, a read pass voltage V_{READ} (refer to c of FIG. 3) which is larger than the upper limit of the threshold voltage distribution C is applied between the gate and the source of a non-read-target non-selected memory cell MC. The read pass voltage V_{READ} is a voltage that has a value larger than that of the upper limit of the threshold voltage distribution C and that enables the memory cell MC to be set to a conductive state irrespective of held data of the memory cell MC.

As described above, the threshold voltage distribution of the write-completed memory cell MC eventually becomes any one of E, A, B, and C (refer to c of FIG. 3). As previously mentioned, these threshold voltage distributions correspond to data “11(E)”, “01(A)”, “10(B)”, and “00(C)”, respectively. That is, two-bit data of one memory cell MC is configured from lower page data and upper page data, and when notated as data “*@”, “*” represents the upper page data, and “@” represents the lower page data.

Now, even in the case of a memory cell MC that has once passed verify and for which write has thereby been completed, there is a possibility that, with passing time, electrons are lost from the floating gate and the threshold voltage lowers, whereby data gets lost. A write method of data for solving this problem will be described below.

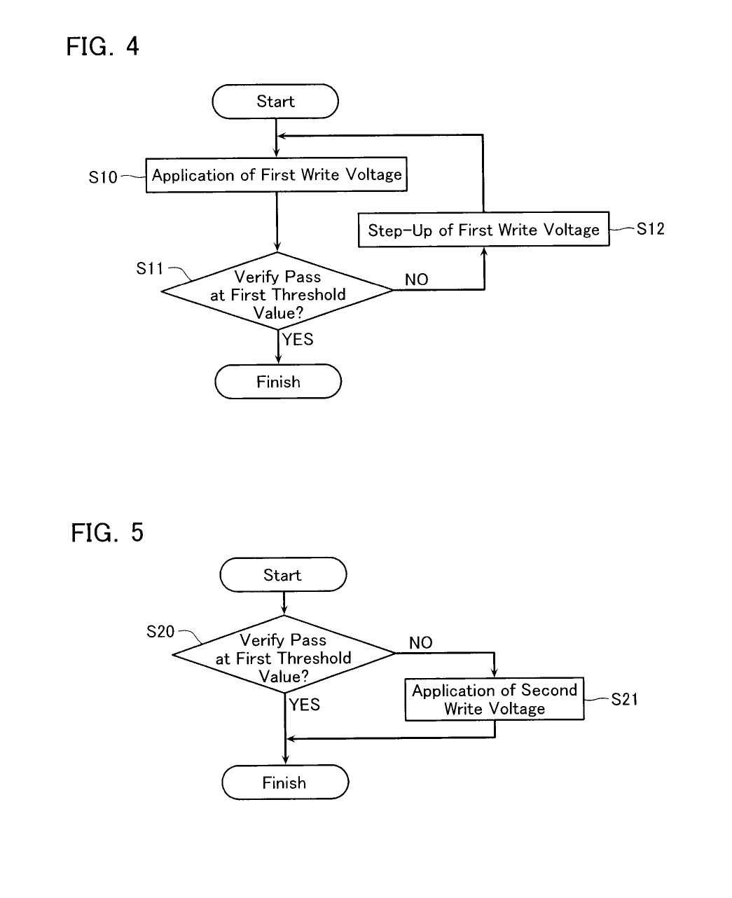

FIGS. 4 and 5 are flowcharts showing a write method of the semiconductor memory device according to the first embodiment. First, as shown in step S10 of FIG. 4, a control circuit (the column control circuit 2 and the row control circuit 3) applies a write voltage (referred to below as “first write voltage” in the present embodiment) to the write-target memory cell MC. Next, the control circuit performs a verify based on a threshold voltage (referred to below as “first threshold value” in the present embodiment) corresponding to data intended to be written to the memory cell MC, and determines whether said verify has been passed or not (step S11).

If the verify has been passed in step S11, the write operation on the memory cell MC once finishes. If the verify has not been passed, the control circuit steps up the first write voltage (step S12) and re-performs write to the memory cell MC by said stepped-up first write voltage (step S10). The control circuit repeats step S10 through step S12 until the memory cell MC passes the verify.

FIG. 5 is a flowchart showing a re-write operation on the memory cell MC that has once passed the verify. First, the control circuit performs a verify based on the same first threshold value as in step S11 of FIG. 4 (step S20). If the verify has been passed in step S20, the control circuit finishes the write operation.

If the verify has not been passed in step S20, the control circuit performs a re-write on the memory cell MC applying a second write voltage (step S21). This second write voltage is distinguished from the previously mentioned first write voltage in being a write voltage applied to the memory cell MC in the re-write operation. Application of the second write voltage is performed once only and the re-write operation finishes.

In the following description of the present embodiment, the initial write operation shown in step S10 of FIG. 4 is referred to as a “first write”, and the verify operation of step Sib following this is referred to as a “first verify”. In addition, as shown in step S20 of FIG. 5, the verify operation on the memory cell MC that has once passed the verify is referred to as a “second verify”, and the re-write operation of step S21 following this is referred to as a “second write”.

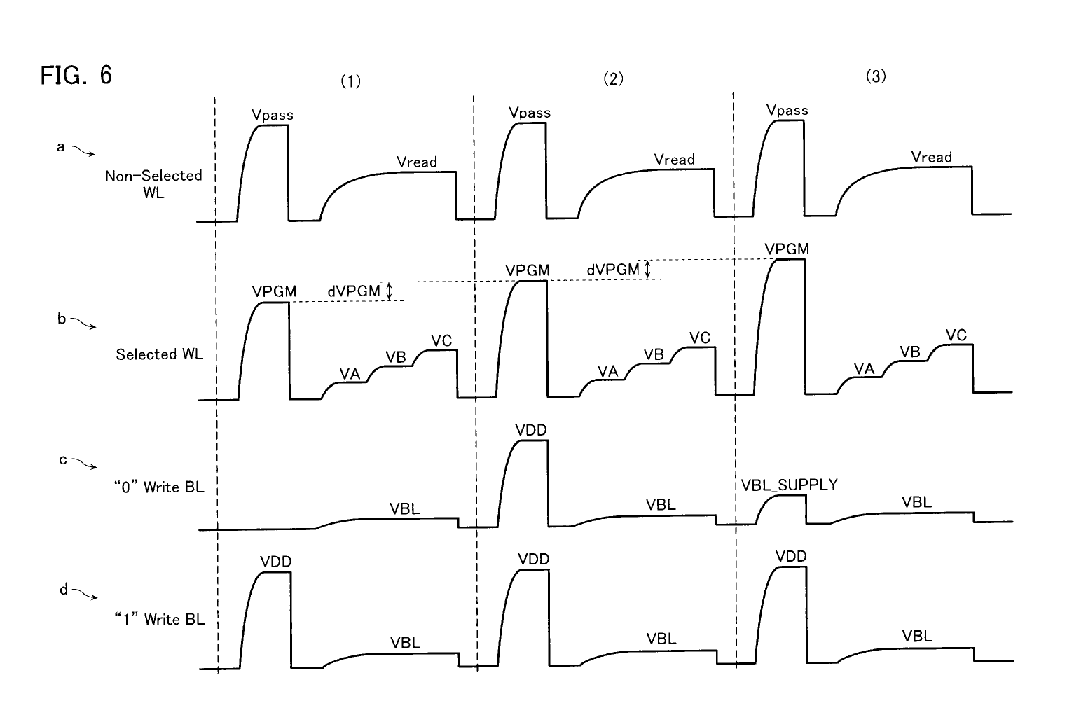

Next, a specific description is given with reference to FIG. 6. FIG. 6 is a signal waveform chart corresponding to the flowcharts of FIGS. 4 and 5, and illustrates a first cycle (1) through a third cycle (3) of the write operation. A voltage of the previously mentioned non-selected word line is shown in a of FIG. 6, and a voltage of the previously mentioned selected word line is shown in b of FIG. 6. A voltage of the bit line electrically connected to the memory cell MC on which “0” write is performed is shown in c of FIG. 6, and a voltage of the bit line electrically connected to the memory cell MC on which “1” write is performed is shown in d of FIG. 6.

As shown in a of FIG. 6, the non-selected word line is applied with a write pass voltage Vpass in a first half of the write cycle, and is applied with a read pass voltage Vread for verify in a second half of the write cycle. This is similar to as previously mentioned in the description of FIG. 3. Next, as shown in b of FIG. 6, the selected word line is applied with a write voltage VPGM in the first half of the write cycle, and is sequentially applied with verify voltages VA, VB, and VC in the second half of the write cycle. As previously mentioned, the present embodiment adopts a step-up system write method, hence the write voltage VPGM rises dVPGM at a time as the write cycles proceed.

Next, as shown in d of FIG. 6, the “1” write (write inhibit) bit line is applied with a power supply voltage VDD in the first half of the write cycle. As a result, as previously mentioned, the channel potential of the memory cell MC attains a floating state and injection of electrons into the floating gate is suppressed, hence write to the memory cell MC is not performed.

Next, the “0” write bit line shown in c of FIG. 6 is applied with a different voltage in the second cycle (2), depending on pass/fail of the verify. Shown in c of FIG. 6 as an example of “0” write is the case where although the verify has been passed in the first cycle (1) (YES in step S11 of FIG. 4), the verify is a fail in the second cycle (2) (NO in step S20 of FIG. 5), and a re-write is performed in the third cycle (3) (second write of step S21). This will be described in detail below.

First, in the first half of the first cycle (1), a potential of the bit line BL is maintained at Vss (=0 V). At this time, the selected word line is applied with the voltage VPGM, and the memory cell MC is applied with the write voltage of VPGM (first write voltage). Following this, in the verify operation of the second half of the first cycle (1), the bit line BL is maintained at a certain potential (VBL). As previously mentioned, the selected word line is sequentially applied with the verify voltages VA, VB, and VC, whereby the verify operation (first verify) is executed. If the first verify has been passed, the operation shifts to the second cycle (2), and if the first verify has not been passed, the first cycle (1) is re-executed. As previously mentioned, c of FIG. 6 shows a waveform of the case where in the first cycle (1), the memory cell MC has passed the verify (first verify).

Next, in the first half of the second cycle (2), the memory cell MC has already passed the first verify, hence the “0” write bit line BL is applied with the power supply voltage VDD in order not to raise the threshold voltage of the memory cell MC. Following this, in the second half of the second cycle (2), the verify operation (second verify) on the memory cell MC that has already passed the verify is performed by a similar method to in the first cycle (1). As previously mentioned, c of FIG. 6 shows a waveform of the case where in the second cycle (2), the memory cell MC has not passed the verify (second verify).

Next, in the first half of the third cycle (3), the memory cell MC that has not passed the verify in the second cycle (2) undergoes the re-write (second write). Specifically, the selected word line is applied with a stepped-up write voltage VPGM+2dVPGM, and the selected bit line BL is applied with a write voltage VBL_SUPPLY for re-write. A value of VBL_SUPPLY is set to a value smaller than VDD−Vth in order to set the select transistor S1 to a conductive state. In the present embodiment, the value of VBL_SUPPLY is a value equal to an amount of increase of the write voltage VPGM in the selected word line from the first cycle (1) to the third cycle (3) (=dVPGM×2). As a result, a write voltage corresponding to a magnitude of “VPGM−VBL_SUPPLY” (second write voltage) is applied between the gate and the channel of the memory cell MC. Said voltage is equal to the first write voltage (VPGM) applied to the memory cell MC in the first cycle (1).

Due to the above-described re-write (second write) in the first half of the third cycle (3), the lowered threshold voltage of the memory cell MC rises and returns to its original voltage distribution. In the second half of the third cycle (3), the verify operation is executed similarly to in the first cycle (1) and the second cycle (2).

Due to the semiconductor memory device according to the first embodiment, the memory cell MC that has once passed the verify (first verify) undergoes a re-verify (second verify). Furthermore, the memory cell that has failed in the second verify undergoes a re-write (second write) using the second write voltage. This makes it possible to deal with the case where the threshold voltage of the memory cell MC has lowered with passing time, and to obtain an appropriate threshold voltage distribution.

The first embodiment described an example where the second write is performed one time only (refer to FIG. 5), but a step-up system write may be performed also in the second write, similarly to in the first write. This will be described below.

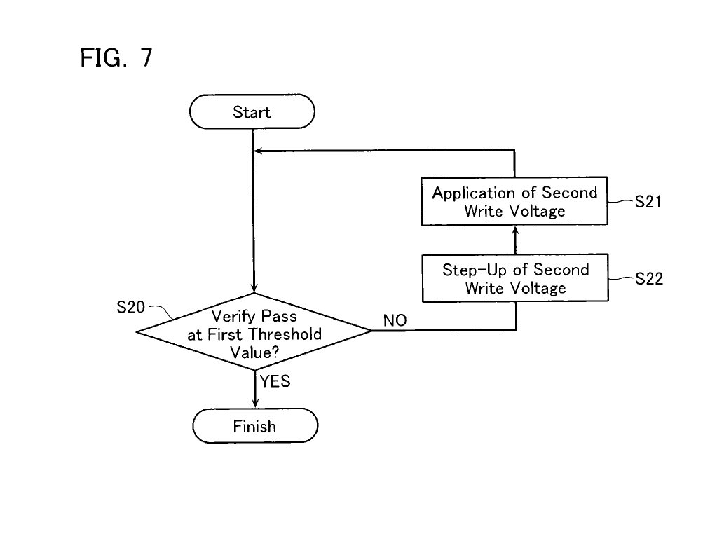

FIG. 7 is a flowchart showing data write of a semiconductor memory device according to a modified example of the first embodiment, and is assumed to have identical reference symbols to those assigned in FIG. 5 assigned in steps shared with FIG. 5. First, the control circuit performs a verify on the memory cell MC based on the first threshold value (step S20). If the verify has been passed in step S20, the control circuit finishes the write operation.

If the verify has not been passed in step S20, the control circuit performs a step-up of the second write voltage (step S22). Following this, the control circuit performs a re-write on the memory cell MC applying the stepped-up second write voltage (step S21). Then, the control circuit returns to a previous stage of step S20 without finishing the write operation, and re-executes the verify operation. The control circuit repeats steps S20, S22, and S21 until the memory cell MC passes the verify based on the first threshold value, and between repetitions, the second write voltage rises (is stepped up) a certain value at a time.

In this way, the step-up system write can be adopted also in the second verify and the second write performed on the memory cell MC that has once passed the verify (first verify), similarly to in the case of the first write.

### Second Embodiment

A second embodiment is an example where the write voltage is changed according to a threshold voltage during verify. A configuration of the semiconductor memory device and threshold distributions of the memory cell MC are similar to those described in the first embodiment (FIGS. 1 to 3), and a detailed description of shared portions will be omitted. Note, in addition to using the previously mentioned VA, VB, and VC, the present embodiment uses in combination therewith VA_Low, VB_Low, and VC_Low which are voltages respectively slightly smaller than VA, VB, and VC, as voltages used during verify. A magnitude relationship of the above-described voltages is VB_Low<VA<VB_Low<VB<VC_Low<VC (refer to FIG. 3).

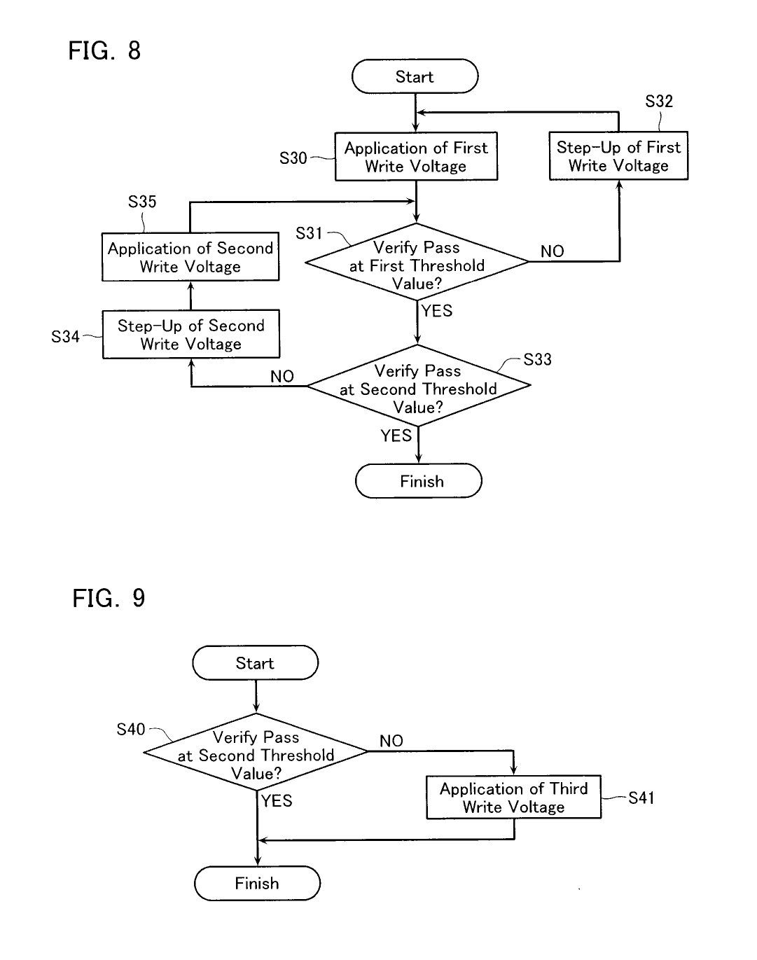

FIGS. 8 and 9 are flowcharts showing a write method of the semiconductor memory device according to the second embodiment. First, as shown in step S30 of FIG. 8, the control circuit applies a write voltage (referred to below as “first write voltage” in the present embodiment) to the word line WL connected to the write-target memory cell MC. Next, the control circuit performs a verify based on a threshold value which is slightly lower than the threshold voltage (referred to below as “first threshold value” in the present embodiment) corresponding to data intended to be written to the memory cell MC, and determines whether said verify has been passed or not (step S31). Note that the above-described first threshold value corresponds to voltages VA_Low, VB_Low, and VC_Low shown in c of FIG. 3.

If the verify has not been passed in step S31, then, similarly to in the case of the first embodiment, the control circuit steps up the first write voltage (step S32) and re-performs write to the memory cell MC by said stepped-up first write voltage (step S30). The control circuit repeats step S30 through step S32 until the memory cell MC passes the verify of the first threshold value.

If the verify has been passed in step S31, the control circuit performs a verify (referred to below as “second verify operation” in the present embodiment) based on a threshold voltage (referred to below as “second threshold value” in the present embodiment) corresponding to data intended to be written to the memory cell MC, and determines whether said verify has been passed or not (step S33). Note that the above-described second threshold value corresponds to voltages VA, VB, and VC shown in c of FIG. 3.

If the verify has been passed in step S31 but the verify has not be en passed in step S33, the control circuit performs a step-up of the second write voltage which is a voltage lower than the first voltage (step S34), and performs a re-write on the memory cell MC applying said stepped-up second write voltage (step S35). Then, the control circuit returns to a previous stage of step S31 and re-executes the verify operation due to the first threshold value.

The memory cell MC that has passed step S31 but has not passed step S33 is thought to be approaching a desired voltage distribution. This indicates that the above-described steps of the second write (steps S34 to S35) reduce the write voltage to suppress an excessive write and narrow the threshold voltage distribution after write. This write operation is referred to below as a “weak write”. The control circuit repeats the steps S31, S33, S34, and S35 until the memory cell MC passes the verify due to the first threshold value and the second threshold value. When the memory cell MC has passed the verify of the second threshold value (“YES” in step S33), the control circuit finishes the write operation. Note that as is clear from steps S34 to S35, in the present embodiment, the step-up system is adopted also in the “weak write”.

FIG. 9 is a flowchart showing a re-write operation on the memory cell MC that has once passed the verify of the first threshold value and the second threshold value. First, the control circuit performs a verify on the memory cell MC based on the same second threshold value as in step S33 of FIG. 8 (step S40). If the verify has been passed in step S40, the control circuit finishes the write operation.

If the verify has not been passed in step S40, the control circuit performs a re-write on the word line WL connected to the memory cell MC applying a third write voltage (step S41). This third write voltage is distinguished from the previously mentioned first write voltage and second write voltage in being a write voltage applied during re-write. Application of the third write voltage is performed once only and the re-write operation finishes.

In the following description of the present embodiment, the write operation in step S30 of FIG. 8 is referred to as a “first write”, and the verify operation of step S31 following this is referred to as a “first verify”. In addition, the verify operation in step S33 of FIG. 8 is referred to as a “second verify”, and the write operation of step S34 following this is referred to as a “second write”. Furthermore, the verify operation on the memory cell MC that has once passed the verify in step S40 of FIG. 9 is referred to as a “third verify”, and the re-write operation of step S41 following this is referred to as a “third write”.

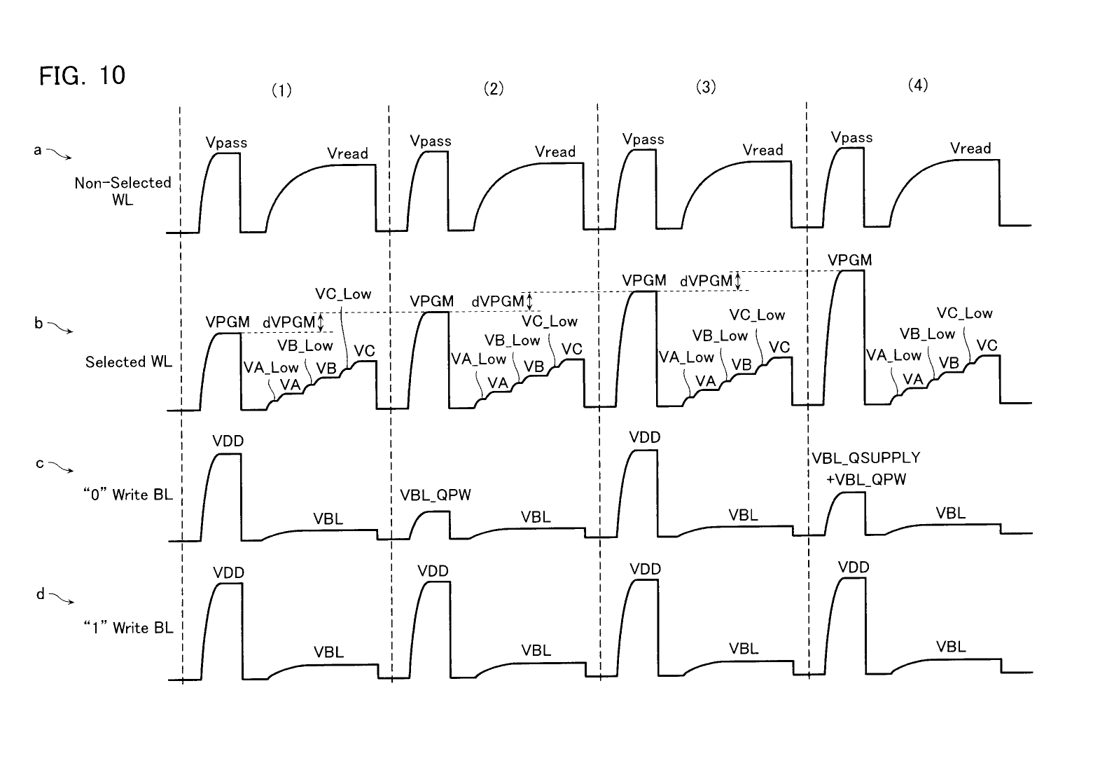

Next, a specific description is given with reference to FIG. 10. FIG. 10 is a signal waveform chart corresponding to the flowcharts of FIGS. 8 and 9, and illustrates a first cycle (1) through a fourth cycle (4) of the write operation. A voltage of the previously mentioned non-selected word line is shown in a of FIG. 10, and a voltage of the previously mentioned selected word line is shown in b of FIG. 10. A voltage of the bit line electrically connected to the memory cell MC on which “0” write is performed is shown in c of FIG. 10, and a voltage of the bit line electrically connected to the memory cell MC on which “1” write is performed is shown in d of FIG. 10. In the present embodiment, the signal waveform charts of the non-selected word line WL in a of FIG. 10 and the “1” write bit line BL in d of FIG. 10 are similar to those of the first embodiment (FIG. 6), hence a detailed description thereof will be omitted.

As shown in b of FIG. 10, the selected word line WL is applied with the write voltage VPGM in the first half of the write cycle, and is sequentially applied with the verify voltages VA_Low, VA, VB_Low, VB, VC_Low, and VC, in order from the lowest, for the verify operation, in the second half of the write cycle. Moreover, the present embodiment also adopts the step-up system write method, and the write voltage VPGM rises dVPGM at a time as the write cycles proceed.

Next, the “0” write bit line shown in c of FIG. 10 is applied with different voltages in the second cycle (2) through fourth cycle (4), depending on pass/fail of the verify. Illustrated in c of FIG. 10 as an example of “0” write is the case where although the first verify (step S31 of FIG. 8) has been passed in the first cycle (1), the second verify (step S33) is a fail, and the second write of a weak write (step S34) is performed in the second cycle (2). Furthermore, shown in c of FIG. 10 is an example where although the second verify (step S33) has been passed in the second cycle (2), the third verify (step S40 of FIG. 9) is a fail in the third cycle (3), and the third write (S41 of FIG. 9) is performed as a re-write in the fourth cycle (4). This will be described in detail below.

First, in the first half of the first cycle (1), a potential of the “0” write bit line BL is maintained at Vss (=0 V). At this time, the selected word line is applied with the voltage VPGM, and the memory cell MC is applied with the write voltage of VPGM (first write voltage). Following this, in the verify operation of the second half of the first cycle (1), the bit line BL is maintained at a certain potential (VBL). As previously mentioned, the selected word line is sequentially applied with the verify voltages VA_Low, VA, VB_Low, VB, VC_Low, and VC, whereby the verify operation (first verify and second verify operation) is executed. As previously mentioned, c of FIG. 10 shows a waveform of the case where in the first cycle (1), the memory cell MC has passed the first verify (verify due to the first threshold value) but has not passed the second verify (verify due to the second threshold value).

Next, in the first half of the second cycle (2), the bit line BL is applied with a voltage VBL_QPW for the weak write. At this time, the selected word line is applied with a voltage VPGM+dVPGM, and the memory cell MC is applied with a write voltage of “VPGM+dVPGM−VBL_QPW”. As a result, the second write (step S34 of FIG. 8) due to the second write voltage (VPGM+dVPGM−VBL_QPW) which is smaller than the ordinary first write voltage (VPGM+dVPGM) is performed as the weak write. As a result, a rise width of the threshold voltage of the memory cell MC is suppressed, and it is difficult for an excessive write to occur.

Following this, in the second half of the second cycle (2), the potential of the bit line is maintained at a certain potential (VBL). As previously mentioned, the selected word line is sequentially applied with the verify voltages VA_Low through VC, whereby the verify operation (first verify and second verify) is executed. As previously mentioned, c of FIG. 10 shows a waveform of the case where in the second cycle (2), the memory cell MC has passed the verify (first verify and second verify).

Next, in the first half of the third cycle (3), the memory cell MC has already passed the first verify and the second verify, hence the “0” write bit line BL is applied with the power supply voltage VDD in order not to raise the threshold voltage of the memory cell MC. Following this, in the second half of the second cycle (2), the verify operation (third verify) on the memory cell MC that has already passed the verify is performed by a similar method to in the first cycle (1). As previously mentioned, c of FIG. 10 shows a waveform of the case where in the third cycle (3), the memory cell MC has not passed the verify (third verify).

Next, in the first half of the third cycle (3), the memory cell MC that has not passed the verify in the second cycle (2) undergoes the re-write (third write).

Specifically, the selected word line WL is applied with a stepped-up write voltage VPGM+3dVPGM, and the selected bit line BL is applied with a write voltage VBL_SUPPLY+VBL_QPW for re-write. In the present embodiment, a value of VBL_SUPPLY is a value equal to an amount of increase of the write voltage VPGM in the selected word line from the second cycle (2) to the fourth cycle (4) (=dVPGM×2). As a result, the memory cell MC is applied with a write voltage corresponding to a magnitude of “VPGM+3dVPGM−(VBL_SUPPLY+VBL_QPW)” (third write voltage). Said voltage is equal to the first write voltage (VPGM+dVPGM-VBL_QPW) applied to the memory cell MC in the second cycle (2). Moreover, the value of VBL_SUPPLY is set to a value smaller than VDD-Vth in order to set the select transistor S1 to a conductive state.

Due to the above-described re-write (third write) in the first half of the fourth cycle (4), the lowered threshold voltage of the memory cell MC rises and returns to its original voltage distribution. In the second half of the fourth cycle (4), the verify operation is executed similarly to in the first cycle (1) through third cycle (3).

Due to the semiconductor memory device according to the second embodiment, the verify is performed using the second threshold value (VA, VB, and VC) corresponding to data intended to be written to the memory cell MC and the first threshold value (VA_Low, VB_Low, and VC_Low) which is lower than said second threshold value. Moreover, the memory cell MC whose threshold voltage is between the first threshold value and the second threshold value undergoes the weak write (second write) using the second write voltage (VPGM−VBL_QPW) which is smaller than the first write voltage (VPGM). As a result, in the memory cell MC whose threshold voltage is slightly short of a target value, the rise width of the threshold voltage is suppressed, and it can be made more difficult for an excessive write to occur.

Furthermore, in the second embodiment, similarly to in the first embodiment, the memory cell MC that has once passed the verify undergoes a re-verify (third verify). Moreover, the memory cell that has failed in the third verify undergoes a re-write (third write) using the third write voltage. This makes it possible to deal with the case where the threshold voltage of the memory cell MC has lowered with passing time, and to obtain an appropriate threshold voltage distribution.

In addition, due to the above-described semiconductor memory device, the third write voltage used during the third write is equal to the first write voltage when the verify operation (first verify operation) at a time of completion of the initial write (first write) has been passed (refer to FIG. 10). This makes it possible to suppress the threshold voltage of the memory cell MC rising more than required by the re-write. Note that a magnitude of the third write voltage may be made smaller than the previously mentioned first write voltage.

The second embodiment described an example where the third write is performed one time only (refer to FIG. 9), but a step-up system write may be performed also in the second write, similarly to in the first write. This will be described below.

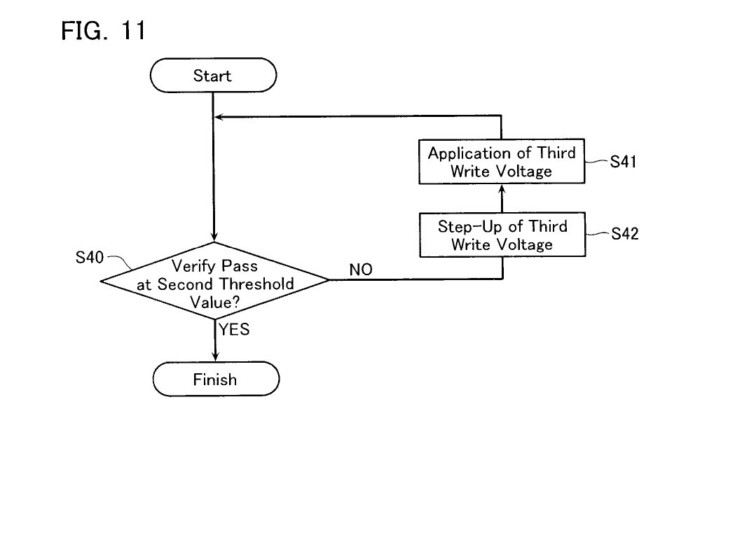

FIG. 11 is a flowchart showing data write of a semiconductor memory device according to a modified example of the second embodiment, and is assumed to have identical reference symbols to those assigned in FIG. 9 assigned in steps shared with FIG. 9. First, the control circuit performs a verify on the memory cell MC based on the second threshold value (step S40). If the verify has been passed in step S40, the control circuit finishes the write operation.

If the verify has not been passed in step S40, the control circuit performs a step-up of the third write voltage (step S42). Following this, the control circuit performs a re-write on the memory cell MC applying the stepped-up third write voltage (step S41). Then, the control circuit returns to a previous stage of step S40 without finishing the write operation, and re-executes the verify operation. The control circuit repeats steps S40, S42, and S41 until the memory cell MC passes the verify based on the second threshold value, and between repetitions, the third write voltage rises (is stepped up) a certain value at a time.

In this way, the step-up system write can be adopted also in the third verify and the third write performed after the verify (first verify and second verify) has once been passed, similarly to in the case of the first write and the second write. This enables a reduction of write time to be achieved.

The semiconductor memory device according to the first through second embodiments adopts a step-up system that increases stepwise the first write voltage applied to the memory cell MC in the first write. This enables a reduction of write time to be achieved.

In addition, the semiconductor memory device according to the first through second embodiments is configured to apply to the bit line BL in the re-write operation a voltage corresponding to an increase portion of the write voltage of the selected word line WL from a time of initial write to a time of re-write (=VBL_SUPPLY). As a result, in the case of adopting the step-up system, it is possible to suppress the write voltage used in re-write increasing more than required.

The method of controlling a semiconductor memory device explained in the first through second embodiments may be applied to an ordinary memory cell array where memory strings (formed by series of memory cells) are arranged in a horizontal direction to the surface of the substrate. The method may be applied also to a 3D (three dimensional) type memory cell array where memory cells are arranged in a lamination direction (a vertical direction to the surface of the substrate). Configurations of 3D type memory cells are described below in detail.

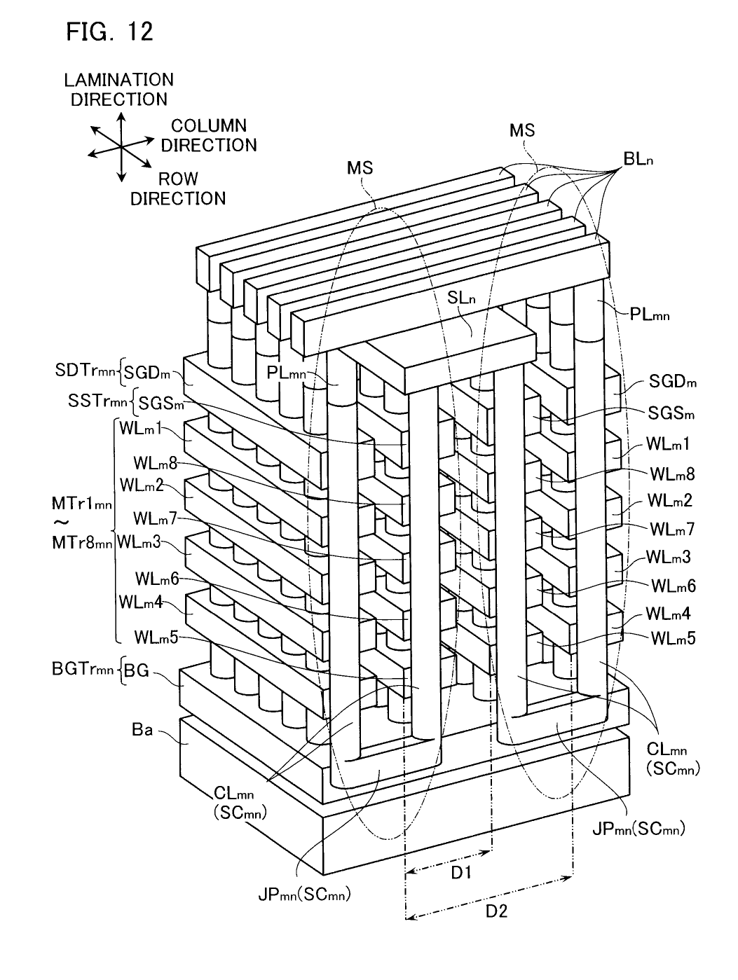

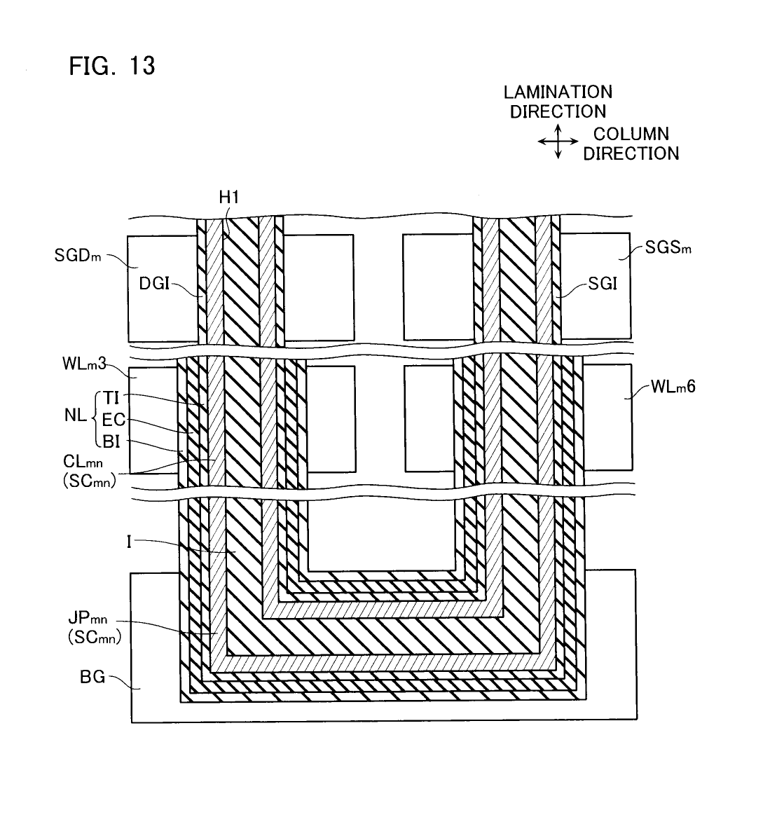

FIG. 12 is a schematic perspective view of a part of the memory transistor region of the semiconductor memory device. The memory transistor region has m×n (m, n are natural numbers) pieces of memory strings MS each composed of the memory transistors (MTr1ₘₙ to MTr8ₘₙ) a source side select gate transistor SSTrₘₙ and a drain side select gate transistor SDTrₘₙ. FIG. 12 shows an example of m=6, n=2. FIG. 13 is a partly enlarged sectional view of FIG. 12.

In the semiconductor memory device, a plurality of the memory strings MS are disposed to the memory transistor region. Although explained below in detail, each of the memory strings MS has such an arrangement that the plurality of electrically rewritable memory transistors MTrₘₙ are connected in series. As shown in FIG. 12, the memory transistors MTrₘₙ constituting each of the memory strings MS is formed by laminating a plurality of semiconductor layers.

Each memory string MS has a U-shaped semiconductor SCₘₙ, word lines WLₘₙ (WLₘ1 to WLₘ8), the source side selection gate line SGSₘ, and the drain side selection gate line SGDₘ. Further, the memory string MS has the back gate line BG.

The U-shaped semiconductor SCₘₙ is formed in a U-shape when viewed from a row direction. The U-shaped semiconductor SCₘₙ has a pair of columnar portions CLₘₙ extending in an approximately vertical direction with respect to a semiconductor substrate Ba and a coupling portion JPₘₙ formed so as to be coupled with lower ends of the pair of columnar portions CLₘₙ. Further, as shown in FIG. 13, the U-shaped semiconductor SCₘₙ has hollow portions H1 which communicates from an upper end of one of the columnar portions CLₘₙ to an upper end of the other columnar portion CLₘₙ through the coupling portion JPₘₙ. An insulating portion I is formed in the hollow portions H1. Note that the columnar portions CLₘₙ may be formed in any of a circular columnar shape and an angular columnar shape. Further, the columnar portions CLₘₙ may be formed in a stepped columnar shape. Here, the row direction is a direction orthogonal to a lamination direction, and a column direction to be described later is a direction orthogonal to a vertical direction and to the row direction.

The U-shaped semiconductor SCₘₙ is disposed such that a linear line connecting the center axes of the pair of columnar portions CLₘₙ is in parallel with the column direction. Further, the U-shaped semiconductors SCₘₙ are disposed such that they are formed in a matrix state in a plane formed in the row direction and the column direction.

The word line WLₘₙ of each layer has a shape extending in parallel with the row direction. The word lines WLₘₙ of the respective layers are repeatedly formed in a line state by being insulated and separated from each other at first intervals formed in the column direction.

Gates of the memory transistors (MTr1ₘₙ to MTr8ₘₙ), which are disposed at the same positions in the column direction and arranged in the row direction, are connected to the same word lines WLₘₙ. The respective word lines WLₘₙ are disposed approximately vertical to the memory strings MS. Ends of the word lines WLₘₙ in the row direction are formed stepwise. Note that the ends of the word lines WLₘₙ in the column direction are not limited to be formed stepwise. For example, the ends of the word lines WLₘₙ in the column direction may be aligned at a certain position in the column direction.

As shown in FIG. 13, an ONO (Oxide-Nitride-Oxide) layer NL is formed between the word line WLₘₙ and the columnar portions CLₘₙ. The ONO layer NL has a tunnel insulation layer TI in contact with the columnar portions CLₘₙ, a charge storage layer EC in contact with the tunnel insulation layer TI, and a block insulation layer BI in contact with the charge storage layer EC. The charge storage layer EC has a function for accumulating charge.

In other words, the charge storage layer EC is formed so as to surround a side surface of the columnar portion CLₘₙ. Further, each word line WLₘₙ is formed so as to surround the side surface of the columnar portion CLₘₙ and the charge storage layer EC. Further, each word line WLₘₙ is divided for each of respective columnar portions CLₘₙ adjacent to each other in the column direction.

The drain side selection gate line SGDₘ is disposed above the uppermost word line WLₘₙ. The drain side selection gate line SGDₘ has a shape extending in parallel with the row direction. The drain side selection gate lines SGDₘ are repeatedly formed in a line state by being insulated and separated from each other at first intervals D1 or second intervals D2 (D2>D1) formed alternately in the column direction. The drain side selection gate lines SGDₘ are formed at second intervals D2 with the source side selection gate line SGSₘ to be described later sandwiched therebetween. Further, the columnar portions CLₘₙ are formed passing through the centers of the drain side selection gate lines SGDₘ in the column direction. As shown in FIG. 13, a gate insulation layer DGI is formed between the drain side selection gate line SGDₘ and the columnar portion CLₘₙ.

The source side selection gate line SGSₘ is disposed above the uppermost word line WLₘₙ. The source side selection gate line SGSₘ has a shape extending in parallel with the row direction. The source side selection gate lines SGSₘ are repeatedly formed in a line state by being insulated and separated from each other at first intervals D1, second intervals D2 formed alternately in the column direction. The source side selection gate line SGSₘ are formed at the second intervals D2 with the drain side selection gate line SGDₘ sandwiched therebetween. Further, the columnar portions CLₘₙ are formed passing through the centers of the source side selection gate line SGSₘ in the column direction. As shown in FIG. 13, a gate insulation layer SGI is formed between the source side selection gate line SGSₘ and the columnar portion CLₘₙ.

In other words, the two drain side selection gate lines SGDₘ and the two source side selection gate lines SGSₘ are alternately formed by forming the first intervals D1 in the column direction. Further, the respective drain side selection gate lines SGDₘ and the respective source side selection gate lines SGSₘ are formed to surround the columnar portions CLₘₙ and the gate insulation layers SGI, DGI. Further, each drain side selection gate line SGDₘ and each source side selection gate line SGSₘ are divided for each of respective columnar portions CLₘₙ adjacent to each other in the column direction.

The back gate line BG is formed to two-dimensionally expand in the row direction and the column direction so as to cover below a plurality of coupling portions JPₘₙ. As shown in FIG. 13, the ONO layer NL described above is formed between the back gate line BG and the coupling portions JPₘₙ.

Further, the source lines SLₙ are formed on upper ends of the columnar portions CLₘₙ of the U-shaped semiconductors SCₘₙ adjacent in the column direction. Further, the bit lines BLₙ are formed on the upper ends of the columnar portions CLₘₙ extending upward of the drain side selection gate lines SGDₘ through plug lines PLₘₙ. The respective bit lines BLₙ are formed to locate on the source lines SLₙ. The respective bit lines BLₙ are repeatedly formed in a line state which extends in the column direction at predetermined intervals formed in the row direction.

Further, the memory cell array 1 may be configured such that at least one of the word line WL or the bit line BL extends vertical to the surface of a substrate in which the memory cell MC is provided.

### Other Embodiments

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a nonvolatile memory cell; and
a control circuit that performs write control on the memory cell,
the control circuit executing:
a first write operation that performs a write on the memory cell using a first write voltage;
a first verify operation that determines whether a threshold voltage of the memory cell exceeds a first threshold value due to the first write operation, or not;
a second verify operation that re-determines on the memory cell that has passed the first verify operation whether the threshold voltage exceeds the first threshold value, or not; and
a second write operation that performs a write on the memory cell that has not passed the second verify operation, using a second write voltage.

2. The semiconductor memory device according to claim 1, wherein
the first write voltage increases stepwise.

3. The semiconductor memory device according to claim 2, wherein
the second write voltage is equal to the first write voltage when the first verify operation has been passed.

4. The semiconductor memory device according to claim 1, wherein
the memory cells are arranged in series, sandwiched by a plurality of select transistors, in a region of intersection of a word line and a bit line.

5. The semiconductor memory device according to claim 4, wherein
the control circuit increases the first write voltage in the first write operation by increasing stepwise a voltage applied to the word line according to a result of the first verify operation.

6. The semiconductor memory device according to claim 5, wherein
in the second write operation, the control circuit applies to the bit line a voltage corresponding to an amount of increase of an applied voltage in the word line.

7. The semiconductor memory device according to claim 4, wherein at least one of the word line or the bit line extends vertical to the surface of a substrate in which the nonvolatile memory cell is provided.

8. The semiconductor memory device according to claim 4, wherein
the memory cells are arranged in a vertical direction with respect to a substrate to form a memory string connected to the bit line via the select transistor,
the memory string comprising:
semiconductor layers having columnar portion extending in a vertical direction with respect to the substrate;
a charge storage layer formed to surround the side surfaces of the columnar portions; and
conductive layers formed to surround the side surfaces of the columnar portions and the charge storage layer,
the conductive layers functioning as the word lines and as gate electrodes of the memory cells.

9. A semiconductor memory device, comprising:
a nonvolatile memory cell; and
a control circuit that performs write control on the memory cell,
the control circuit executing:
a first write operation that performs a write on the memory cell using a first write voltage;
a first verify operation that determines whether a threshold voltage of the memory cell exceeds a first threshold value due to the first write operation, or not;
a second verify operation that determines whether the threshold voltage of the memory cell exceeds a second threshold value larger than the first threshold value due to the first write operation, or not;
a second write operation that performs a write on the memory cell that has passed the first verify operation and has not passed the second verify operation, using a second write voltage smaller than the first write voltage;
a third verify operation that re-determines on the memory cell that has passed the second verify operation whether the threshold voltage exceeds the second threshold value, or not; and
a third write operation that performs a write on the memory cell that has not passed the third verify operation, using a third write voltage.

10. The semiconductor memory device according to claim 9, wherein
the first write voltage and the second write voltage increase stepwise.

11. The semiconductor memory device according to claim 10, wherein
the third write voltage is equal to the second write voltage when the second verify operation has been passed.

12. The semiconductor memory device according to claim 9, wherein
the memory cells are arranged in series, sandwiched by a plurality of select transistors, in a region of intersection of a word line and a bit line.

13. The semiconductor memory device according to claim 10, wherein
the control circuit increases the first write voltage in the first write operation by increasing stepwise a voltage applied to the word line according to a result of the first verify operation.

14. The semiconductor memory device according to claim 13, wherein
in the second write operation, the control circuit applies the second voltage to the memory cell by applying to the bit line a certain voltage larger than that applied to the bit line during the first write operation.

15. The semiconductor memory device according to claim 14, wherein
in the third write operation, the control circuit applies to the bit line a voltage that corresponds to a total of a voltage corresponding to an amount of increase of an applied voltage in the word line and the certain voltage in the second write operation.

16. A method of controlling a semiconductor memory device, the semiconductor memory device comprising a nonvolatile memory cell, the method comprising:
performing a first write that performs a write on the memory cell using a first write voltage;
performing a first verify that determines whether a threshold voltage of the memory cell exceeds a first threshold value due to the first write step, or not;
performing a second verify that re-determines on the memory cell that has passed the first verify step whether the threshold voltage exceeds the first threshold value, or not; and
performing a second write that performs a write on the memory cell that has not passed the second verify step, using a second write voltage.
